(19) United States
(12) Patent Application Publication
(10) Pub. No.: US 2026/0088108 A1
(43) Pub. Date: Mar. 26, 2026

(54) MEMORY DEVICE, MEMORY SYSTEM INCLUDING MEMORY DEVICE, AND METHOD OF OPERATING MEMORY DEVICE

(71) Applicant: SK hynix Inc., Gyeonggi-do (KR)

(72) Inventor: Jae Woong KIM, Gyeonggi-do (KR)

(21) Appl. No.: 19/084,766

(22) Filed: Mar. 20, 2025

(30) Foreign Application Priority Data
Sep. 24, 2024 (KR) 10-2024-0128902

(51) Int. Cl. G11C 16/34; G11C 16/26; G11C 16/30

(52) U.S. Cl. CPC G11C 16/3418; G11C 16/26; G11C 16/30

(57) ABSTRACT

A memory device may include a memory block connected to a plurality of word lines, a voltage generator configured to generate read voltages to be applied to a selected word line during a read operation and a read retry operation, and a control logic configured to control the voltage generator to perform the read operation and the read retry operation. The voltage generator is underdriven or overdriven to generate read voltages based on an underdrive level or an overdrive level corresponding to the read voltages. The control logic is configured to control the voltage generator to perform the read retry operation by applying an offset to the underdrive level or overdrive level based on variation between read voltages used in the read operation and the read voltages, levels of which are newly set in the read retry operation.

### CROSS-REFERENCE TO RELATED APPLICATION

The present application claims priority under 35 U.S.C. § 119(a) to Korean patent application number 10-2024-0128902, filed on Sep. 24, 2024, the entire disclosure of which is incorporated by reference herein.

### BACKGROUND

### 1. Field of Invention

Various embodiments of the present disclosure relate to an electronic device, and more particularly to a memory device, a memory system including the memory device, and a method of operating the memory device.

### 2. Description of Related Art

A memory system is a device which stores data under the control of a host, such as a computer or a smartphone. The memory system may include a memory device which stores data and a memory controller which controls the memory device. Memory devices are classified into volatile memory devices and nonvolatile memory devices.

A volatile memory device may be a memory device in which data is stored only when power is supplied and in which stored data is lost when the supply of power is interrupted. Examples of the volatile memory device may include a static random access memory (SRAM) and a dynamic random access memory (DRAM).

A nonvolatile memory device is a memory device in which stored data is retained even when the supply of power is interrupted. Examples of the nonvolatile memory device may include a read only memory (ROM), a programmable ROM (PROM), an electrically programmable ROM (EPROM), an electrically erasable and programmable ROM (EEPROM), and a flash memory.

### SUMMARY

Various embodiments of the present disclosure are directed to a memory device, a memory system including the memory device, and a method of operating the memory device, which can improve operation speed by quickly charging or discharging the potential level of a word line to a set level during a read operation.

An embodiment of the present disclosure may provide for a memory device. The memory device may include a memory block connected to a plurality of word lines, and a voltage generator configured to generate a plurality of read voltages during a read operation and a plurality of read voltages during a read retry operation, the plurality of read voltages generated during the read operation and the plurality of read voltages generated during the read retry operation to be applied to a selected word line among the plurality of word lines. The memory device further includes a control logic configured to control the voltage generator to perform the read operation and the read retry operation on the memory block. The voltage generator is underdriven or overdriven to generate each of the plurality of read voltages based on an underdrive level or an overdrive level respectively corresponding to the plurality of read voltages.

The control logic is configured to control the voltage generator to perform the read retry operation by applying an offset to the underdrive level or the overdrive level based on a variation between the plurality of read voltages generated in the read operation and the plurality of read voltages generated in the read retry operation, where levels of the plurality of read voltages generated in the read retry operation are newly set in the read retry operation.

An embodiment of the present disclosure may provide for a memory system. The memory system may include a memory device configured to store data, and read and output data during a read operation, and a memory controller configured to receive the data from the memory device and control the memory device to perform a read retry operation based on a number of error bits contained in the received data. The memory device is configured to set an underdrive level or an overdrive level during the read retry operation based on a level variation between read voltages used during the read operation and read voltages to be used during the read retry operation, and to generate the read voltages at the underdrive level or the overdrive level during the read retry operation.

An embodiment of the present disclosure may provide for a method of operating a memory device. The method may include performing a read operation on memory cells connected to a selected word line using a plurality of read voltages, and when the read operation is determined to have failed, performing a read retry operation on the memory cells using a plurality of new read voltages obtained by changing levels of the plurality of read voltages used in the read operation, wherein the performing of the read retry operation includes adjusting an underdrive level or an overdrive level of each of the plurality of new read voltages based on a variation between each of the plurality of read voltages used in the read operation and each of the plurality of new read voltages used in the read retry operation.

### BRIEF DESCRIPTION OF THE DRAWINGS

FIG. 1 is a diagram of a memory system including a memory device according to an embodiment of the present disclosure.

FIG. 2 is a diagram of a structure of the memory device of FIG. 1 according to an embodiment of the present disclosure.

FIG. 3 is a diagram illustrating an embodiment of a memory cell array of FIG. 2 according to an embodiment of the present disclosure.

FIG. 4 is a circuit diagram of any one of a plurality of memory blocks BLK1 to BLKz illustrated in FIG. 3 according to an embodiment of the present disclosure.

FIG. 5 is a circuit diagram of memory cell strings illustrated in FIG. 4 according to an embodiment of the present disclosure.

FIG. 6 is a diagram for explaining a read operation of a memory device according to an embodiment of the present disclosure.

FIG. 7 is a diagram for explaining a read retry operation of a memory device according to an embodiment of the present disclosure.

FIG. 8 is a flowchart illustrating a method of operating a memory device according to an embodiment of the present disclosure.

FIGS. 9, 10, and 11 are waveform diagrams for explaining an example of a read operation according to an embodiment of the present disclosure.

FIG. 12 is a diagram for explaining a read retry operation of FIG. 8 according to an embodiment of the present disclosure.

FIGS. 13, 14, and 15 are waveform diagrams for explaining an example of a read retry operation according to an embodiment of the present disclosure.

FIGS. 16, 17, and 18 are waveform diagrams for explaining an example of a read operation according to an embodiment of the present disclosure.

FIGS. 19, 20, and 21 are waveform diagrams for explaining an example of a read retry operation according to an embodiment of the present disclosure.

FIG. 22 is a block diagram illustrating a memory card system to which a memory system according to an embodiment of the present disclosure may be applied.

FIG. 23 is a block diagram illustrating a solid state drive (SSD) system to which a memory system according to an embodiment of the present disclosure may be applied.

FIG. 24 is a block diagram illustrating a user system to which a memory system according to an embodiment of the present disclosure may be applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

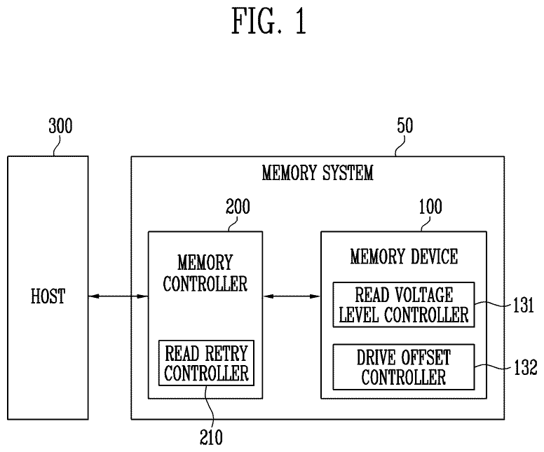

FIG. 1 is a diagram of a memory system 50 including a memory device 100 according to an embodiment of the present disclosure.

Referring to FIG. 1, the memory system 50 may include the memory device 100 and a memory controller 200. The memory system 50 may be a device which stores data under the control of a host 300, such as a mobile phone, a smartphone, an MP3 player, a laptop computer, a desktop computer, a game console, a television (TV), a tablet PC, or an in-vehicle infotainment system.

The memory system 50 may be manufactured as any one of various types of storage devices depending on a host interface, that is a scheme for communication with the host 300. For example, the memory system 50 may be implemented as any one of various types of storage devices, for example, a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-e or PCIe) card-type storage device, a compact flash (CF) card, a smart media card, and a memory stick.

The memory system 50 may be manufactured in any one of various types of package forms. For example, the memory system 50 may be manufactured in any one of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may be operated in response to the control of the memory controller 200. The memory device 100 may include a memory cell array including a plurality of memory cells which store data.

Each of the memory cells may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

The memory cell array may include a plurality of memory blocks. Each memory block may include a plurality of memory cells. One memory block may include a plurality of pages. In an embodiment, each page may be the unit by which data is stored in the memory device 100 or by which data stored in the memory device 100 is read. A memory block may be the unit by which data is erased.

In an embodiment, the memory device 100 may be a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM), a NAND flash memory, a vertical NAND flash memory, a NOR flash memory, a resistive RAM (RRAM), a phase-change random access memory (PRAM), a magnetoresistive RAM (MRAM), a ferroelectric RAM (FRAM), a spin transfer torque RAM (STT-RAM), or the like. In the present specification, for convenience of description, description will be made on the assumption that the memory device 100 is a NAND flash memory.

The memory device 100 may receive a command and an address from the memory controller 200, and may access the area of the memory cell array selected by the address. The memory device 100 may perform an operation indicated by the command on the area selected by the address. For example, the memory device 100 may perform a write operation (program operation), a read operation, or an erase operation. During a write operation, the memory device 100 may program data to the area selected by the address. During a read operation, the memory device 100 may read data from the area selected by the address. During an erase operation, the memory device 100 may erase data stored in the area selected by the address.

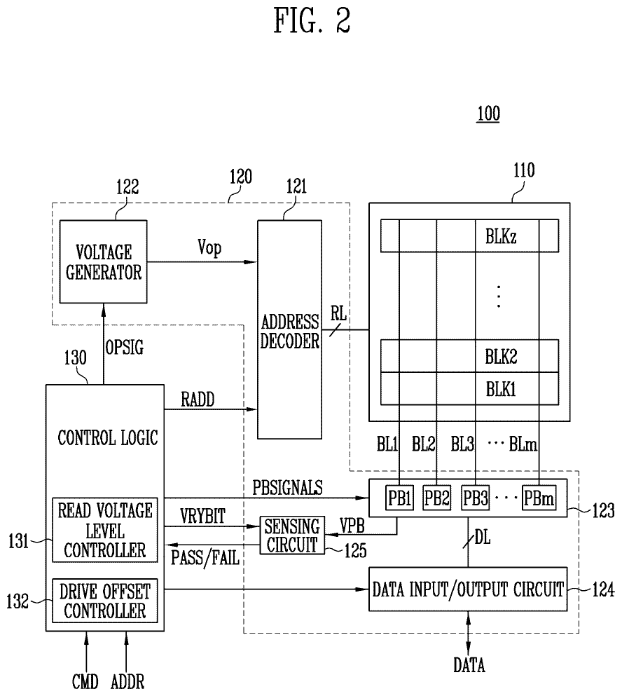

In an embodiment, the memory device 100 may include a read voltage level controller 131 and a drive offset controller 132. The read voltage level controller 131 may set the levels of a plurality of read voltages to be applied to a word line connected to selected memory cells during a read operation on the memory cells, and may control a voltage generator of the memory device 100 (e.g., voltage generator 122 in FIG. 2) to generate read voltages having the set levels.

Different read voltages may be available for implementing a read operation. This is because the threshold voltage of individual memory cells can vary over time due to wear and tear, meaning that a single read voltage might not reliably distinguish between a “0” and a “1” for all cells. According to an embodiment of the present disclosure, when this happens, the read operation may be retried using different read voltages in an attempt to accurately read data from selected memory cells. By using different read voltages, the system can therefore attempt to read data even when cell thresholds have shifted, improving data reliability.

The drive offset controller 132 may adjust and set the overdrive level or the underdrive level of the voltage generator of the memory device 100, so that the potential of the word line connected to the selected memory cells is quickly charged or discharged to the levels of the set read voltages during the read operation on the memory cells. The drive offset controller 132 may also control the voltage generator to generate a plurality of read voltages at the set overdrive level or underdrive level.

The memory controller 200 may control the overall operation of the memory system 50. When power is applied to the memory system 50, the memory controller 200 may run firmware (FW). When the memory device 100 is a flash memory device, the firmware (FW) may include a host interface layer (HIL) which controls communication with the host 300, a flash translation layer (FTL) which controls communication between the host 300 and the memory device 100, and a flash interface layer (FIL) which controls communication with the memory device 100.

In an embodiment, the memory controller 200 may receive data and a logical block address (LBA) from the host 300, and may translate the logical block address (LBA) into a physical block address (PBA) indicating the address of memory cells which are included in the memory device 100 and in which data is to be stored. In the present specification, a logical block address (LBA) and a “logical address” may be used interchangeably with each other. In the present specification, a physical block address (PBA) and a “physical address”may be used interchangeably with each other.

The memory controller 200 may control the memory device 100 to perform a write operation, a read operation or an erase operation in response to a request received from the host 300. During a write operation, the memory controller 200 may provide a write command, a physical block address, and data to the memory device 100. During a read operation, the memory controller 200 may provide a read command and a physical block address to the memory device 100. During an erase operation, the memory controller 200 may provide an erase command and a physical block address to the memory device 100.

In an embodiment, the memory controller 200 may independently generate a command, an address, and data regardless of whether a request from the host 300 is received, and may transmit them to the memory device 100. For example, the memory controller 200 may provide the memory device 100 with commands, addresses, and data which are required for performing read operations and write operations associated with performance of wear leveling, read reclaim, garbage collection, etc.

In an embodiment, the memory controller 200 may control at least two memory devices 100. In this case, the memory controller 200 may control the memory devices 100 depending on an interleaving scheme to improve operating performance. The interleaving scheme may be a scheme for controlling the memory devices 100 so that the operations of at least two memory devices 100 overlap each other.

The memory controller 200 may include a read retry controller 210. The read retry controller 210 may receive data read from the memory device 100 on which the read operation is performed, and may correct erroneously read data by performing an error correction decoding operation on the data received from the memory device 100. For example, the read retry controller 210 may perform error correction decoding of correcting error bits contained in the data using parity bits generated in a low density parity check (LDPC) encoding process. However, when a number of error bits greater than or equal to an error bit limit correctable by error correction decoding occurs, the read retry controller 210 may determine that the read operation of the memory device 100 has failed, and may control the memory device 100 to perform a read retry operation of retrying a read operation by changing the levels of the read voltages.

The memory device 100 may perform a read retry operation under the control of the read retry controller 210. For example, the read voltage level controller 131 may newly set the levels of the read voltages in response to an instruction from the read retry controller 210, and control the voltage generator of the memory device 100 to generate read voltages having the newly set levels. The drive offset controller 132 may calculate variation (or difference) between the read voltages used in the read operation and the read voltages to be used in the read retry operation. Also, the drive offset controller 132 may adjust the overdrive level and the underdrive level by applying an offset to an initially set overdrive level and an initially set underdrive level based on the calculated variation. The drive offset controller 132 may then control the voltage generator to generate a plurality of read voltages at the overdrive level and the underdrive level adjusted through application of the offset.

The host 300 may communicate with the memory system 50 using at least one of various communication methods such as universal serial bus (USB), serial AT attachment (SATA), serial attached SCSI (SAS), high speed Interchip (HSIC), small computer system Interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

FIG. 2 is a diagram of a structure of the memory device 100 of FIG. 1 according to an embodiment of the present disclosure.

Referring to FIG. 2, the memory device 100 may include a memory cell array 110, a peripheral circuit 120, and a control logic 130. The control logic 130 may be implemented in hardware (e.g., control circuit IC), software, or a combination of hardware and software.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz may be connected to a page buffer group 123 through bit lines BL1 to BLm. Each of the memory blocks BLK1 to BLKz may include a plurality of memory cells connected to corresponding ones of a plurality of word lines. In an embodiment, the plurality of memory cells may be nonvolatile memory cells. Memory cells connected to the same word line among the plurality of memory cells are defined as one page. Thus, the memory cell array 110 may include a plurality of pages. In accordance with an embodiment of the present disclosure, each of the memory blocks BLK1 to BLKz included in the memory cell array 110 may include a plurality of dummy cells. For the dummy cells, one or more dummy cells may be connected in series between a drain select transistor and memory cells and between a source select transistor and memory cells.

Each of the memory cells of the memory device 100 may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

The peripheral circuit 120 may drive the memory cell array 110. In an example, the peripheral circuit 120 may drive the memory cell array 110 to perform a program operation, a read operation, and an erase operation under the control of the control logic 130. In an example, the peripheral circuit 120 may apply various driving voltages (operating voltages) Vop to the row lines RL and the bit lines BL1 to BLm or discharge the applied voltages under the control of the control logic 130.

The peripheral circuit 120 may include the address decoder 121, a voltage generator 122, the page buffer group 123, a data input and output (input/output) circuit 124, and a sensing circuit 125.

The address decoder 121 is connected to the memory cell array 110 through the row lines RL. The row lines RL may include drain select lines, word lines, source selection lines, and a common source line. In accordance with an embodiment of the present disclosure, the word lines may include normal word lines and dummy word lines. In accordance with an embodiment of the present disclosure, the row lines RL may further include a pipe select line. The address decoder 121 may be operated under the control of the control logic 130. The address decoder 121 receives addresses ADDR from the control logic 130.

The address decoder 121 may decode a block address among the received addresses ADDR. The address decoder 121 may select at least one of the memory blocks BLK1 to BLKz according to the decoded block address. The address decoder 121 may decode a row address RADD among the received addresses ADDR. The address decoder 121 may select at least one word line WL of the selected memory block by applying voltages supplied from the voltage generator 122 to the at least one word line WL according to the decoded row address RADD.

During a program operation, the address decoder 121 may apply a program voltage to the selected word line and apply, to unselected word lines, a pass voltage, having a level less than that of the program voltage. During a program verify operation, the address decoder 121 may apply a verify voltage to the selected word line and apply, to the unselected word lines, a verify pass voltage, having a level greater than that of the verify voltage.

During a read operation, the address decoder 121 may apply a read voltage to the selected word line and apply a pass voltage, having a level higher than that of the read voltage, to the unselected word lines. When the read operation fails, the read retry controller 210 may execute a read retry operation for the selected word line, as described herein.

An erase operation of the memory device 100 may be performed on a memory block basis. During the erase operation, addresses ADDR input to the memory device 100 include a block address. The address decoder 121 may decode the block address and select one memory block according to the decoded block address. During the erase operation, the address decoder 121 may apply a ground voltage to word lines connected to the selected memory block.

The address decoder 121 may decode a column address among the received addresses ADDR. The decoded column address may be transferred to the page buffer group 123. In an embodiment, the address decoder 121 may include components, such as a row decoder, a column decoder, and an address buffer.

The voltage generator 122 may generate a plurality of driving voltages Vop using an external supply voltage that is supplied to the memory device 100. The voltage generator 122 may be operated under the control of the control logic 130.

In an embodiment, the voltage generator 122 may generate an internal supply voltage by regulating the external supply voltage. The internal supply voltage generated by the voltage generator 122 may be used as a driving voltage for the memory device 100.

In an embodiment, the voltage generator 122 may generate various driving voltages Vop that are used for program, read, and erase operations in response to an operation signal OPSIG from the control logic 130. The voltage generator 122 may generate the plurality of driving voltages Vop using the external supply voltage or the internal supply voltage. The voltage generator 122 may generate various voltages required by the memory device 100. For example, the voltage generator 122 may generate a plurality of erase voltages, a plurality of program voltages, a plurality of read voltages, and a plurality of pass voltages.

The voltage generator 122 may include a plurality of pumping capacitors for receiving the internal supply voltage to generate a plurality of driving voltages Vop having various voltage levels. The voltage generator 122 may generate the plurality of driving voltages Vop by selectively enabling the plurality of pumping capacitors under the control of the control logic 130.

In an embodiment, the voltage generator 122 may generate a plurality of read voltages to be applied to a selected word line during a read operation, and may be overdriven or underdriven so that the selected word line is quickly charged or discharged to a set level. For example, when the potential of the selected word line is less than a read voltage level, the voltage generator 122 may generate the read voltage for a certain time by designating the read voltage level as an overdrive level greater than a set value, thus quickly charging the potential level of the selected word line. The voltage generator 122 may generate the read voltage by lowering the read voltage level back to the set value after the certain time has elapsed. Further, when the potential of the selected word line is greater than the read voltage level, the voltage generator 122 may generate the read voltage for a certain time by designating the read voltage level as an underdrive level less than the set value, thus quickly discharging the potential level of the selected word line. The voltage generator 122 may generate the read voltage by increasing the read voltage level back to the set value after the certain time has elapsed.

The page buffer group 123 includes first to m-th page buffers PB1 to PBm. The first to m-th page buffers PB1 to PBm are connected to the memory cell array 110 through the first to m-th bit lines BL1 to BLm, respectively. The first to m-th page buffers PB1 to PBm are operated under the control of the control logic 130, e.g., based on page buffer control signals PBSIGNALS output from control logic 130.

The first to m-th page buffers PB1 to PBm perform data communication with the data input/output circuit 124. During a program operation, the first to m-th page buffers PB1 to PBm may receive data DATA to be stored from the data input/output circuit 124 and data lines DL.

During a program operation, the first to m-th page buffers PB1 to PBm may transfer the data DATA to be stored, received through the data input/output circuit 124, to selected memory cells through the bit lines BL1 to BLm when a program pulse is applied to a selected word line. Memory cells in a selected page may be programmed based on the transferred data DATA. Memory cells connected to a bit line to which a program-enable voltage (e.g., a ground voltage) is applied may have increased threshold voltages. The threshold voltages of memory cells connected to a bit line to which a program-inhibit voltage (e.g., a supply voltage) is applied may be maintained. During a program verify operation, the first to m-th page buffers PB1 to PBm may read the data DATA stored in the selected memory cells from the selected memory cells through the bit lines BL1 to BLm.

During a read operation, the page buffer group 123 may read data DATA from the memory cells in the selected page through the bit lines BL1 to BLm, and may store the read data DATA in the first to m-th page buffers PB1 to PBm. The data DATA may be read from the memory cells of the selected page using the plurality of read voltages described herein, including read voltages having newly set levels applied during a read retry operation.

During an erase operation, the page buffer group 123 may allow the bit lines BL1 to BLm to float. In an embodiment, the page buffer group 123 may include a column select circuit.

In an embodiment, while pieces of data stored in some of the plurality of page buffers included in the page buffer group 123 are being programmed to the memory cell array 110, the remaining page buffers may receive new data from the memory controller 200 and then store the new data.

The data input/output circuit 124 is connected to the first to m-th page buffers PB1 to PBm through the data lines DL. The data input/output circuit 124 may be operated in response to the control of the control logic 130.

The data input/output circuit 124 may include a plurality of input/output buffers which receive input data DATA. During a program operation, the data input/output circuit 124 receives the data DATA to be stored from an external controller. During a read operation, the data input/output circuit 124 outputs the data DATA, received from the first to m-th page buffers PB1 to PBm included in the page buffer group 123, to the external controller.

During a read operation or a verify operation, the sensing circuit 125 may generate a reference current in response to an enable bit signal VRYBIT generated by the control logic 130, and may output a pass signal or a fail signal to the control logic 130 by comparing a sensing voltage VPB received from the page buffer group 123 with a reference voltage generated by the reference current. In an example, the sensing circuit 125 may output the pass signal to the control logic 130 when the magnitude of the sensing voltage VPB is smaller than that of the reference voltage. In an example, the sensing circuit 125 may output the fail signal to the control logic 130 when the magnitude of the sensing voltage VPB is greater than that of the reference voltage.

The control logic 130 may be connected to the address decoder 121, the voltage generator 122, the page buffer group 123, the data input/output circuit 124, and the sensing circuit 125. The control logic 130 may control the overall operation of the memory device 100. The control logic 130 may be operated in response to a command CMD transmitted from an external device, e.g., host 300.

The control logic 130 may control the peripheral circuit 120 by generating various types of signals in response to the command CMD and the addresses ADDR. For example, the control logic 130 may generate the operation signal OPSIG, the row address RADD, page buffer control signals PBSIGNALS, and the enable bit signal VRYBIT in response to the command CMD and the addresses ADDR. The control logic 130 may output the operation signal OPSIG to the voltage generator 122, output the row address RADD to the address decoder 121, output the page buffer control signals PBSIGNALS to the page buffer group 123, and output the enable bit signal VRYBIT to the sensing circuit 125. In addition, the control logic 130 may determine whether a verify operation has passed or failed in response to the pass or fail signal PASS or FAIL output from the sensing circuit 125.

The read voltage level controller 131 and the drive offset controller 132 illustrated in FIG. 1 may be included in the control logic 130. During a read operation, the read voltage level controller 131 may set the levels of a plurality of read voltages to be applied to a word line connected to selected memory cells, and may control the voltage generator 122 to generate read voltages having the set levels.

During a read retry operation, the read voltage level controller 131 may change and reset the levels of a plurality of read voltages to be applied to word lines connected to selected memory cells, and may control the voltage generator 122 to generate read voltages having the reset (or new) levels. The read voltage level controller 131 may change and reset the levels of the plurality of read voltages based on a read retry table including level information of the plurality of read voltages. The read retry table may be stored in any one of the plurality of memory blocks BLK1 to BLkz, and may be read and stored in the control logic 300 during a booting operation of the memory device 100.

The drive offset controller 132 may adjust and set the overdrive level or the underdrive level of the voltage generator 122 so that the potential of the word line connected to the selected memory cells is quickly charged or discharged to the levels of the set read voltages during the read operation on the memory cells, and may control the voltage generator 122 to generate a plurality of read voltages at the set overdrive level or underdrive level for a certain time.

Further, the drive offset controller 132 may calculate a variation between the read voltages used in the (normal) read operation and the read voltages to be used in the read retry operation, and may determine an overdrive offset or an underdrive offset based on the calculated variation. The drive offset controller 132 may set a new overdrive level or underdrive level by applying the overdrive offset or the underdrive offset to the initially set overdrive level or the initially set underdrive level, and may control the voltage generator 122 to generate read voltages having the new overdrive level or underdrive level.

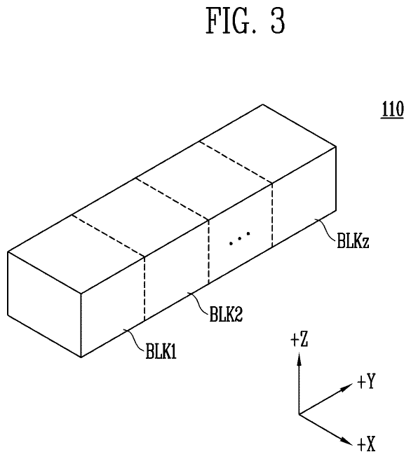

FIG. 3 is a diagram illustrating an embodiment of the memory cell array 100 of FIG. 2 according to an embodiment of the present disclosure.

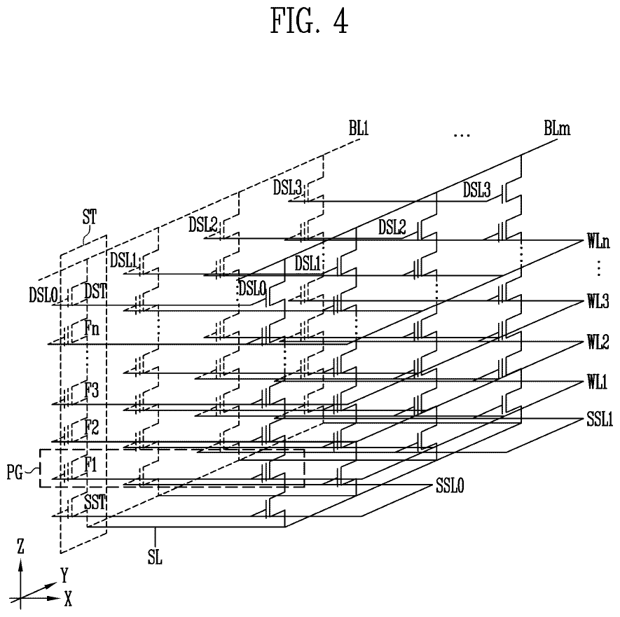

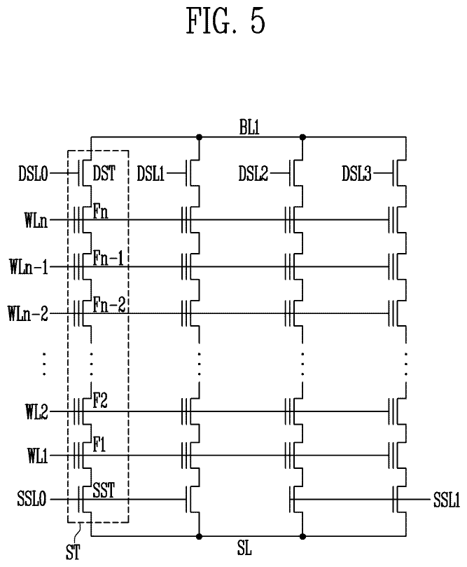

Referring to FIG. 3, the memory cell array 110 includes a plurality of memory blocks BLK1 to BLKz. Each of the memory blocks may have a three-dimensional (3D) structure. Each of the memory blocks includes a plurality of memory cells stacked on a substrate. The plurality of memory cells are arranged in +X, +Y, and +Z directions. The structure of each memory block will be described in detail below with reference to FIGS. 4 and 5.

FIG. 4 is a circuit diagram of any one of a plurality of memory blocks BLK1 to BLKz illustrated in FIG. 3 according to an embodiment of the present disclosure. FIG. 5 is a circuit diagram of memory cell strings ST illustrated in FIG. 4 according to an embodiment of the present disclosure.

Referring to FIGS. 4 and 5, each memory cell string ST may be connected between one of a plurality of bit lines BL1 to BLm and a source line SL. The memory cell string ST connected between the first bit line BL1 and the source line SL will be described by way of example.

The memory cell string ST may include a source select transistor SST, memory cells F1 to Fn (where n is a positive integer), and a drain select transistor DST which are connected in series between the source line SL and the first bit line BL1. Gates of source select transistors SST, included in different memory cell strings ST connected to different bit lines BL1 to BLm, may be connected to a first source select line SSL0 or may be connected to a second source select line SSL1. For example, source select transistors adjacent to each other in a second direction Y among source select transistors SST may be connected to the same source select line.

For example, assuming that the source select transistors SST are sequentially arranged in the second direction Y, gates of source select transistors SST, which are arranged in a first direction X from a first source select transistor SST and are included in different memory cell strings ST, and gates of source select transistors SST, which are arranged in the first direction X from a second source select transistor SST and are included in different memory cell strings ST, may be connected to the first source select line SSL0. Further, gates of source select transistors SST, which are arranged in the first direction X from a third source select transistor SST and are included in different memory cell strings ST, and gates of source select transistors SST, which are arranged in the first direction X from a fourth source select transistor SST and are included in different memory cell strings ST, may be connected to the second source select line SSL1.

Gates of the memory cells F1 to Fn may be connected to the word lines WL1 to WLn, respectively, and gates of the drain select transistors DST may be connected to any one of first to fourth drain select lines DSL0 to DSL3.

Gates of transistors arranged in the first direction X among the drain select transistors DST may be connected in common to the same drain select line (e.g., DSL0), but gates of transistors arranged in the second direction Y may be connected to different drain select lines DSL0 to DSL3. For example, assuming that the drain select transistor DST are sequentially arranged in the second direction Y, gates of drain select transistors DST, which are arranged in the first direction X from a first drain select transistor DST and are included in different memory cell strings ST, may be connected to the first drain select line DSL0. Gates of drain select transistors DST arranged in the second direction Y from the drain select transistors DST connected to the first drain select line DSL0 may be sequentially connected to the second to fourth drain select lines DSL1 to DSL3.

Therefore, in a selected memory block, memory cell strings ST connected to a selected drain select line may be selected, and memory cell strings ST connected to the remaining drain select lines, that is, unselected drain select lines, may be unselected. For example, when the first drain select line DSL0 is selected, memory cell strings connected to the first drain select line DSL0 may be the selected memory cell strings, and memory cell strings connected to the second to fourth drain select lines DSL1 to DSL3 may be the unselected memory cell strings. Further, the first drain select line DSL0 may be the selected drain select line, and the second to fourth drain select lines DSL1 to DSL3 may be the unselected drain select lines. Furthermore, when the first drain select line DSL0 is selected, the first source select line SSL0 may be a selected source select line, and the second source select line SSL1 may be an unselected source select line.

Memory cells connected to the same word line may form a single page (PG). Here, the page may refer to a physical page. For example, in the memory cell strings ST connected to the first bit line BL1 to the m-th bit line BLm, a group of memory cells connected in the first direction X in the same word line is referred to as a page (PG). For example, among the first memory cells F1 connected to the first word line WL1, memory cells arranged in the first direction X may form a single page (PG). Among the first memory cells F1 connected in common to the first word line WL1, memory cells arranged in the second direction Y may be divided into different pages. Therefore, when the first drain select line DSL0 is a selected drain select line and the first word line WL1 is a selected word line, a page connected to the first drain select line DSL0, among a plurality of pages connected to the first word line WL1, may be a selected page. Pages that are connected in common to the first word line WL1, but are connected to unselected second to fourth drain select lines DSL1 to DSL3 may be unselected pages.

In an embodiment, when memory cells are programmed according to a TLC scheme in which three bits of data are stored in each memory cell, data stored in one page may be multi-page data. For example, the multi-page data may include a plurality of logical pages. In detail, the plurality of logical pages may include a least significant bit (LSB) page, a central significant bit (CSB) page, and a most significant bit (MSB) page.

Although, in the drawings, one source select transistor SST and one drain select transistor DST are illustrated as being included in one memory cell string ST, a plurality of source select transistors SST and drain select transistors DST may be included in one memory cell string ST depending on the memory device. Furthermore, dummy cells may be included between the source select transistor SST, the memory cells F1 to Fn, and the drain select transistor DST depending on the memory device. Although the dummy cells do not store user data like normal memory cells F1 to Fn, the dummy cells may be used to improve electrical characteristics of each memory cell string ST.

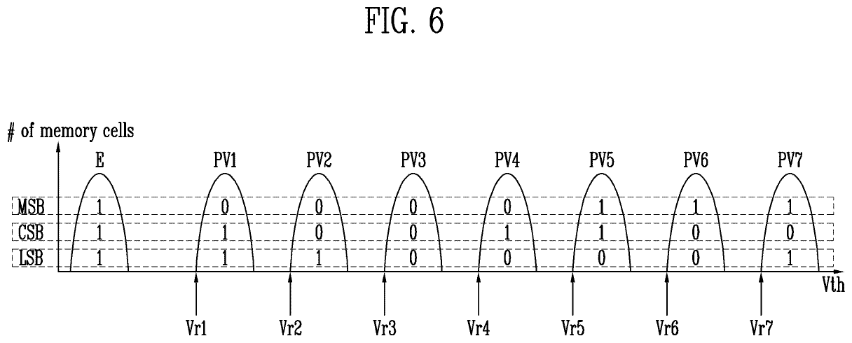

FIG. 6 is a diagram for explaining a read operation of the memory device 100 according to an embodiment of the present disclosure. In FIG. 6, a horizontal axis of the graph denotes the threshold voltages Vth of memory cells, and a vertical axis thereof denotes the number of memory cells ( #of memory cells). Also, in FIG. 6, description will be made on the assumption that memory cells are programmed according to a TLC scheme in which one memory cell stores three bits of data.

Referring to FIG. 6, the threshold voltages of a plurality of memory cells may be increased to threshold voltages corresponding to any one of an erase state E and first to seventh program states PV1 to PV7 through a program operation. Thereafter, the memory device 100 may perform a read operation of obtaining data stored in memory cells. For example, when a read voltage is applied to a word line connected to selected memory cells among the plurality of memory cells, the memory device 100 may detect currents changed on bit lines connected to the selected memory cells, and may then sense data stored in the selected memory cells. The data stored in the memory cells may vary depending on the program states of the memory cells. In detail, different pieces of data may be stored in the memory cells depending on the state to which the threshold voltages of the memory cells correspond among the erase state E and the first to seventh program states PV1 to PV7.

In an embodiment, the memory device 100 may perform a read operation on each of a plurality of logical pages using a plurality of read voltages. The plurality of logical pages may include a least significant bit (LSB) page, a central significant bit (CSB) page, and a most significant bit (MSB) page. For example, as shown in FIG. 6, when the LSB page corresponding to the erase state E and the first to seventh program states PV1 to PV7 is 11100001, a read operation may be performed on the LSB page using a third read voltage Vr3 and a seventh read voltage Vr7 for distinguishing 1 from 0. When the CSB page corresponding to the erase state E and the first to seventh program states PV1 to PV7 is 11001100, a read operation may be performed on the CSB page using a second read voltage Vr2, a fourth read voltage Vr4, and a sixth read voltage Vr6 for distinguishing 1 from 0. When the MSB page corresponding to the erase state E and the first to seventh program states PV1 to PV7 is 10000111, a read operation may be performed on the MSB page using a first read voltage Vr1 and a fifth read voltage Vr5 for distinguishing 1 from 0.

In an embodiment, bits included in the LSB page, the CSB page, and the MSB page may be stored as values different from those illustrated in FIG. 6. In this case, the read voltages for performing the read operation on the LSB page, the CSB page, and the MSB page may vary. For example, although, in FIG. 6, the case where the number of read voltages used for the read operation on the LSB page is 2 has been described, the read operation may be performed using three read voltages depending on the bits included in the LSB page. That is, the magnitudes and number of read voltages for distinguishing 1 from 0 may vary depending on the bits included in the LSB page, the CSB page, and the MSB page.

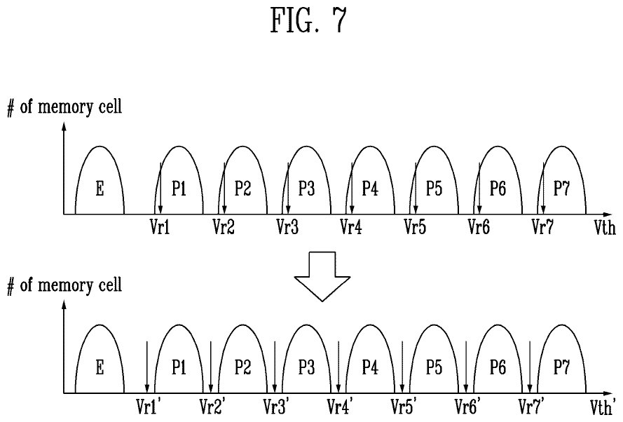

FIG. 7 is a diagram for explaining a read retry operation of a memory device according to an embodiment of the present disclosure. Referring to FIG. 7, distributions of memory cells programmed to an erase state E or first to seventh program states P1 to P7 are illustrated.

When a read voltage, having a level at which it is impossible to clearly identify the program states of selected memory cells, is applied during a sensing operation, a read fail may occur indicating that the result of the read operation is not reliable. For example, when the level of the applied voltage is lower than the maximum value of an on-cell distribution or is higher than the minimum value of an off-cell distribution, a read fail may occur. For example, when the level of the read voltage for distinguishing the erase state E from the first program state P1 is Vr1, some of memory cells to be operated as off-cells may be operated as on-cells. Similarly, the read voltages Vr2 to Vr7 for distinguishing the remaining program states, for example, the second to seventh program states P2 to P7, are set to inappropriate levels. As a result, errors may be contained in the read data.

During a decoding operation, the memory controller 200 of FIG. 1 may perform error correction decoding on erroneously read data. When the memory controller 200 determines that a number of error bits greater than or equal to an error bit limit correctable by error correction decoding occur, the read retry controller 210 of the memory controller 200 may control the memory device 100 to perform a read retry operation using read voltages having newly set levels indicated, for example, in a read retry table.

Specifically, the memory device 100 may perform a read retry operation of retrying a read operation by changing the levels of the read voltages. The memory device 100 may determine the level of the read voltage at which the read operation passes by repeating the read retry operation. For example, the memory device 100 may determine the new level of the first read voltage to be Vr1′ by performing the read retry operation. Similarly, the memory device 100 may determine the new levels of the second to seventh read voltages to be Vr2′ to Vr7′. Variations between the new levels of the read voltages and the original (or normal) levels of the read voltages may then be used as a basis for determining overdrive offset or underdrive offset for performing the read retry operation.

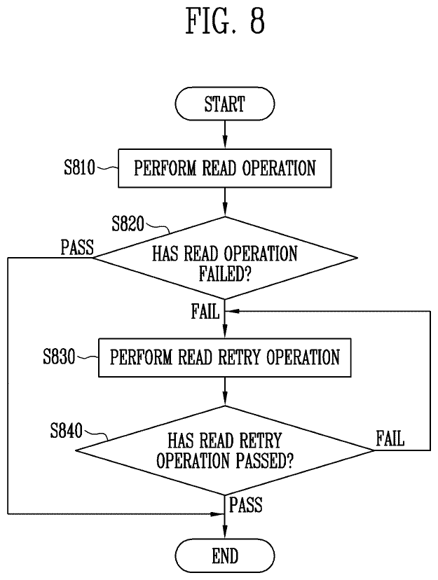

FIG. 8 is a flowchart illustrating a method of operating the memory device 100 according to an embodiment of the present disclosure. The method of operating the memory device according to an embodiment of the present disclosure will be described below with reference to FIGS. 1 and 8.

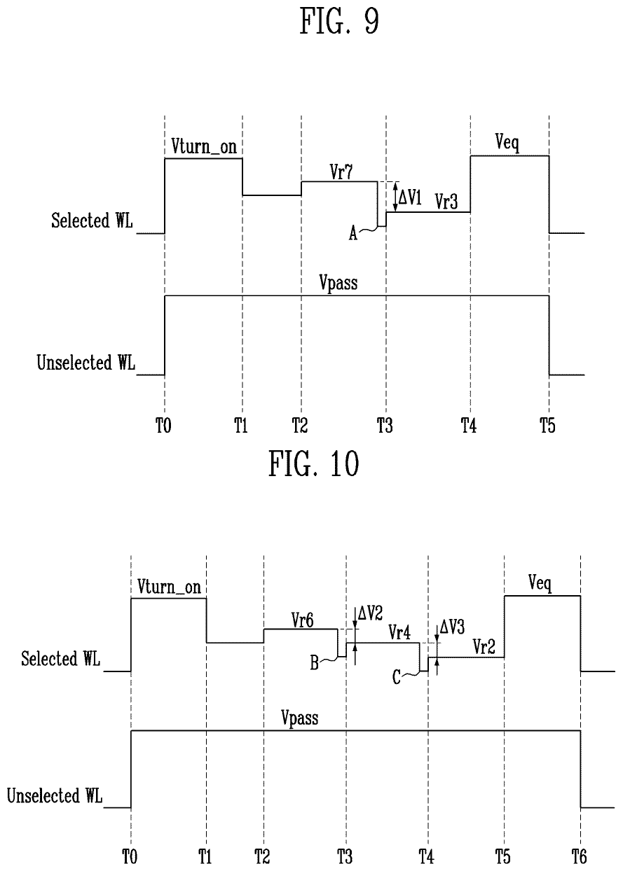

Referring to FIG. 8, at S810, the memory system 50 may perform a read operation in response to a read request received from the host 300. In detail, the memory controller 200 of the memory system 50 may output a read command and an address to the memory device 100 in response to the read request received from the host 300, and the memory device 100 may perform a read operation of reading stored data based on the read command and the address received from the memory controller 200. An example of the read operation performed at 810 is discussed below with respect to FIGS. 9, 10, and 11.

The data obtained as a result of the above-described read operation may be transmitted to the memory controller 200, and the read retry controller 210 of the memory controller 200 may correct erroneously read data by performing an error correction decoding operation on the data received from the memory device 100.

At S820, the memory controller 200 may determine whether the read operation has passed or failed by determining whether the number of error bits contained in the data received from the memory device 100 is equal to or greater than, or less than, the error bit limit correctable by error correction decoding.

When the number of error bits is less than the error bit limit correctable by error correction decoding (S820, pass), the read retry controller 210 may correct the error bits in the data received from the memory device 100 and may transmit the corrected data to the host 300.

When the number of error bits is equal to or greater than the error bit limit correctable by error correction decoding (S820, fail), at S830, the read retry controller 210 may control the memory device 100 to perform a read retry operation. The read retry operation retries the read operation based on a changed level of a read voltage. More specifically, the memory device 100 may receive a command for the read retry operation from the memory controller 200, and may perform the read retry operation by changing the level of the read voltage used in the read operation based on the command. Thereafter, data that is read as a result of the read retry operation is output to the memory controller 200.

At S840, the memory controller 200 may determine whether the read retry operation has passed or failed by determining whether the number of error bits contained in the data received from the memory device 100, on which the read retry operation has been performed, is equal to or greater than, or less than, the error bit limit correctable by error correction decoding.

When the number of error bits is less than the error bit limit correctable by error correction decoding (pass), the read retry controller 210 may correct the error bits in the data received from the memory device 100 and may transmit the corrected data to the host 300. When the number of error bits is equal to or greater than the error bit limit correctable by error correction decoding (fail), the read retry controller 210 may control the memory device 100 to perform an additional read retry operation. The additional read retry operation may retry a read operation based on another changed level of the read voltage, e.g., a read voltage having a level different from the level of the read voltage used in the original read operation and the level of the read voltage used in the first read retry operation.

FIGS. 9, 10, and 11 are waveform diagrams for explaining an example of a read operation according to an embodiment of the present disclosure. The initial read operation performed in S810 of FIG. 8 will be described in detail below with reference to FIGS. 1, 2, 9, 10, and 11.

In an embodiment of the present disclosure, description will be made on the assumption that memory cells are programmed according to a TLC scheme in which one memory cell stores three bits of data. When the memory cells are programmed according to the TLC scheme, the read operation may be sequentially performed in the order of a read operation on an LSB page, a read operation on a CSB page, and a read operation on an MSB page. The read operation on the LSB page will be described below with reference to FIG. 9.

During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may, for example, lie between a seventh read voltage Vr7 and a third read voltage Vr3.

During a period from T2 to T3, the voltage generator 122 may generate the seventh read voltage Vr7 for a certain time, and the address decoder 121 may apply the seventh read voltage Vr7, generated by the voltage generator 122, to the selected word line Selected WL. The page buffer group 123 may read data DATA from memory cells connected to the selected word line Selected WL through the bit lines BL1 to BLm, and may store the read data DATA in first to m-th page buffers PB1 to PBm. Thereafter, in order to quickly generate a third read voltage Vr3 having a level lower than that of the seventh read voltage Vr7 by a first value ΔV1, the voltage generator 122 may be underdriven in the period between T2 and T3 to generate a voltage (e.g., see A in FIG. 9) lower than the third read voltage Vr3 by a certain level.

During a period from T3 to T4, the voltage generator 122 may generate the third read voltage Vr3, and the address decoder 121 may apply the third read voltage Vr3, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

The read operation on the CSB page will be described below with reference to FIG. 10. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may, for example, lie between a sixth read voltage Vr6 and one or more of a fourth read voltage Vr4 and a second read voltage Vr2.

During a period from T2 to T3, the voltage generator 122 may generate the sixth read voltage Vr6 for a certain time, and the address decoder 121 may apply the sixth read voltage Vr6, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate the fourth read voltage Vr4 having a level lower than that of the sixth read voltage Vr6 by a second value ΔV2, the voltage generator 122 may be underdriven to generate a voltage (e.g., see B in FIG. 10) lower than the fourth read voltage Vr4 by a certain level.

During a period from T3 to T4, the voltage generator 122 may generate the fourth read voltage Vr4 for a certain time, and the address decoder 121 may apply the fourth read voltage Vr4, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate the second read voltage Vr2 having a level lower than that of the fourth read voltage Vr4 by a third value ΔV3, the voltage generator 122 may be underdriven to generate a voltage (e.g., see C in FIG. 10) lower than the second read voltage Vr2 by a certain level.

During a period from T4 to T5, the voltage generator 122 may generate the second read voltage Vr2, and the address decoder 121 may apply the second read voltage Vr2, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T5 to T6, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

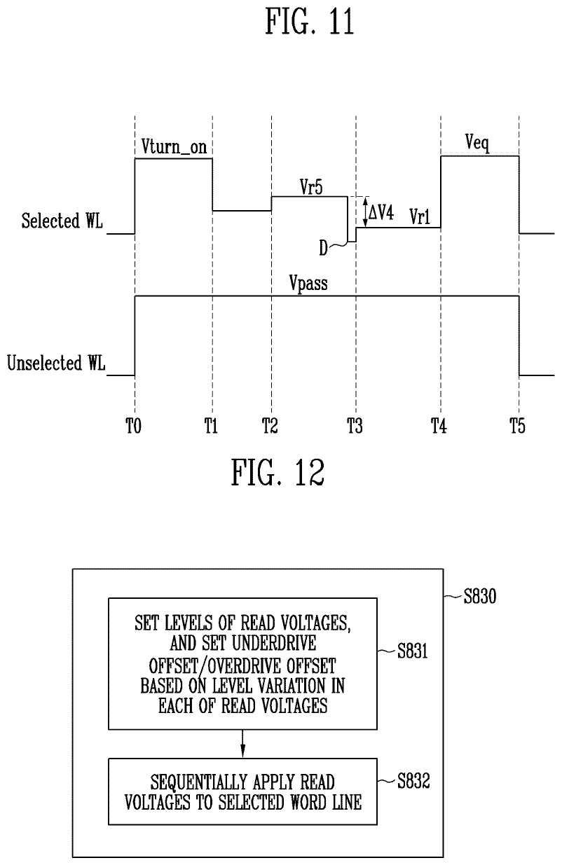

The read operation on the MSB page will be described below with reference to FIG. 11. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may, for example, lie between a fifth read voltage Vr5 and a first read voltage Vr1.

During a period from T2 to T3, the voltage generator 122 may generate a fifth read voltage Vr5 for a certain time, and the address decoder 121 may apply the fifth read voltage Vr5, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a first read voltage Vr1 having a level lower than that of the fifth read voltage Vr5 by a fourth value ΔV4, the voltage generator 122 may be underdriven to generate a voltage (e.g., see voltage D in FIG. 11) lower than the first read voltage Vr1 by a certain level.

During a period from T3 to T4, the voltage generator 122 may generate the first read voltage Vr1, and the address decoder 121 may apply the first read voltage Vr1, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

As described above, the read voltages applied in the read operation on the LSB page, the read operation on the CSB page, and the read operation on the MSB page, respectively, may be sequentially applied in the order from a read voltage having a higher level. For example, the read voltages applied for each of the LSB page, CSB page, and MSB page may be a set of progressively lower voltages.

FIG. 12 is a diagram of the read retry operation in S830 of FIG. 8 according to an embodiment of the present disclosure.

Referring to FIGS. 2 and 12, at S831, the read voltage level controller 131 may change and newly set the levels of a plurality of read voltages during the read retry operation. The drive offset controller 132 may calculate variation between the read voltages to be used in the read retry operation and the read voltages used in the original read operation. The drive offset controller 132 may then set an overdrive offset or an underdrive offset based on the calculated variation. For example, the read voltage level controller 131 may change and set the levels of the plurality of read voltages based on a read retry table including level information of the plurality of read voltages.

For example, in performing S831, the drive offset controller 132 may set underdrive offset values based on respective difference values between the plurality of read voltages used in the original read operation (e.g., S810 of FIG. 8) and the plurality of read voltages, the levels of which are changed and newly set, during the read retry operation. For example, respective underdrive offset values of the plurality of read voltages to be used in the read retry operation may be set based on (1) respective difference values between the plurality of read voltages used in the read operation and the plurality of read voltages which have levels of that are changed and newly set for the read retry operation and (2) proportional constant values respectively corresponding to the plurality of read voltages.

At S832, the voltage generator 122 may sequentially generate the plurality of read voltages with the changed and newly set levels under the control of the read voltage level controller 131. The address decoder 123 may perform a read retry operation by applying the plurality of read voltages for the read retry operation to the selected word line.

When the voltage generator 122 sequentially generates the plurality of read voltages, the drive offset controller 132 may control the voltage generator 122 to be underdriven to the set levels just before the plurality of read voltages are generated, based on the underdrive offset values.

In an embodiment, when, during a read operation or a read retry operation, a read voltage having a lower potential among the plurality of read voltages is first applied to the selected word line. Thereafter, a read voltage having a higher potential is applied to the selected word line. In this case, the voltage generator 122 may be overdriven to generate a voltage having a level higher than that of the next read voltage, so that the next read voltage is quickly generated to have a higher potential after the read voltage having the lower potential is generated. (In this case, the read voltages are set to be progressively higher over corresponding time periods). Here, the drive offset controller 132 may control the voltage generator 122 to be overdriven to the set levels just before the plurality of read voltages are generated, based on overdrive offset values.

For example, the drive offset controller 132 may set overdrive offset values based on respective difference values between the plurality of read voltages used in the read operation (e.g., S810 of FIG. 8) and the plurality of read voltages having levels which are changed and newly set during the read retry operation. For example, respective overdrive offset values of the plurality of read voltages to be used in the read retry operation may be set based on (1) respective difference values between the plurality of read voltages used in the read operation and the plurality of read voltages having levels which are changed and newly set for the read retry operation and (2) proportional constant values respectively corresponding to the plurality of read voltages.

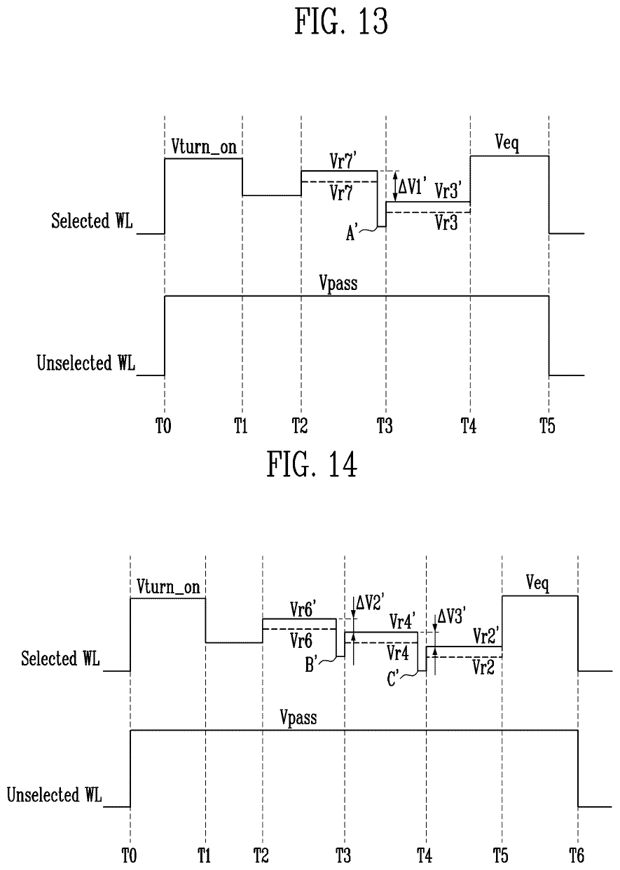

FIGS. 13, 14, and 15 are waveform diagrams for explaining an example of the read retry operation S830 according to an embodiment of the present disclosure. The read retry operation may be performed after the memory controller 200 determines that the read operation performed in FIGS. 9, 10, and 11 has failed. A read retry operation according to an embodiment of the present disclosure will be described below for LSB, CSB, and MSB pages with reference to FIGS. 2, 13, 14 and 15. In these examples, the read voltages are applied to be progressively lower during the read retry operation S830, and therefore the voltage generator 122 may be underdriven at least once depending on the number of read voltages to be applied.

A read retry operation performed on an LSB page will be described below with reference to FIG. 13. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The potential may be discharged to a level lower than the read voltage (e.g., Vr7′) to be initially applied during the read retry operation for the LSB page.

During a period from T2 to T3, the voltage generator 122 may generate a seventh read voltage Vr7′ for a certain time, and the address decoder 121 may apply the seventh read voltage Vr7′, generated by the voltage generator 122, to the selected word line Selected WL. The seventh read voltage Vr7′ may have a higher level than the level of the seventh read voltage Vr7 applied during the read operation S810. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a third read voltage Vr3′ having a level lower than that of the seventh read voltage Vr7′ by a first value ΔV1′, the voltage generator 122 may be underdriven to generate a voltage (e.g., see voltage A′ in FIG. 13) lower than the third read voltage Vr3′ by a certain level. Here, the voltage generator 122 may be underdriven to a new underdrive level, in which an offset is applied to an initially set underdrive level (e.g., the underdrive level used in the read operation), under the control of the drive offset controller 132. Thus, the new underdrive level in the read retry operation (e.g., voltage A′) may be different from the underdrive level (e.g., see voltage A in FIG. 9) in the read operation S810.

During a period from T3 to T4, the voltage generator 122 may generate the third read voltage Vr3′, and the address decoder 121 may apply the third read voltage Vr3′, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

A read retry operation on a CSB page will be described below with reference to FIG. 14. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharge potential may be lower than the read voltage (e.g., Vr6′) to be initially applied in this example.

During a period from T2 to T3, the voltage generator 122 may generate a sixth read voltage Vr6′ for a certain time, and the address decoder 121 may apply the sixth read voltage Vr6′, generated by the voltage generator 122, to the selected word line Selected WL. The sixth read voltage Vr6′ may be higher than the read voltage Vr6 applied during the read operation S810. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a fourth read voltage Vr4′ having a level lower than that of the sixth read voltage Vr6′ by a second value ΔV2′, the voltage generator 122 may be underdriven to generate a voltage (e.g., voltage B′) lower than the fourth read voltage Vr4′ by a certain level. Here, the voltage generator 122 may be underdriven to a new underdrive level, in which an offset is applied to an initially set underdrive level (e.g., the underdrive level used in the read operation), under the control of the drive offset controller 132. Thus, the new underdrive level in the read retry operation (e.g., voltage B′ in FIG. 14) may be different from the underdrive level (e.g., see voltage B in FIG. 10) in the read operation S810.

During a period from T3 to T4, the voltage generator 122 may generate the fourth read voltage Vr4′ for a certain time, and the address decoder 121 may apply the fourth read voltage Vr4′, generated by the voltage generator 122, to the selected word line Selected WL. The fourth read voltage Vr4′ may be higher than the fourth read voltage Vr4 applied in the read operation S810. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a second read voltage Vr2′ having a level lower than that of the fourth read voltage Vr4′ by a third value ΔV3′, the voltage generator 122 may be underdriven to generate a voltage (e.g., voltage C′ in FIG. 14) lower than the second read voltage Vr2′ by a certain level. Here, the voltage generator 122 may be underdriven to a new underdrive level, in which an offset is applied to an initially set underdrive level (e.g., the underdrive level used in the read operation), under the control of the drive offset controller 132. Thus, the new underdrive level in the read retry operation (e.g., voltage C′) may be different from the underdrive level (e.g., see voltage C in FIG. 10) in the read operation S810.

During a period from T4 to T5, the voltage generator 122 may generate the second read voltage Vr2′, and the address decoder 121 may apply the second read voltage Vr2′, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T5 to T6, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

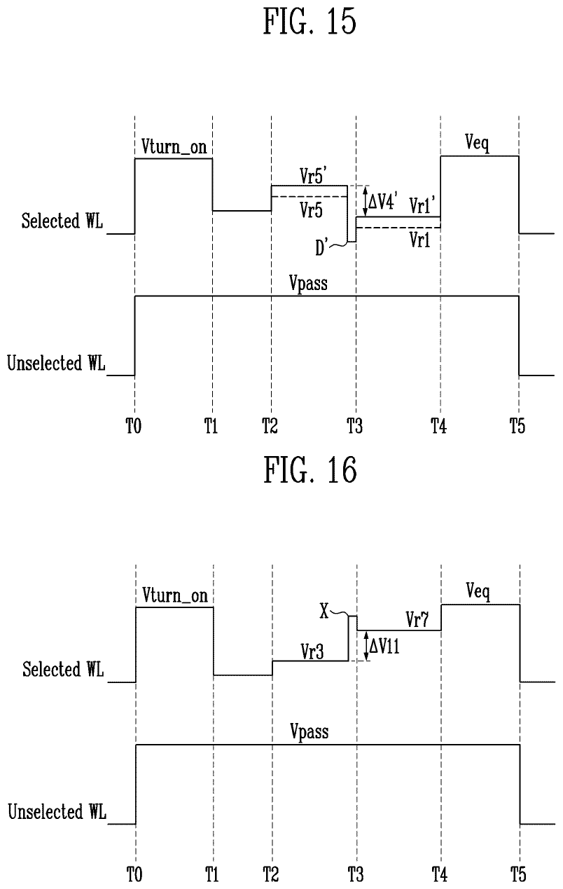

A read retry operation on an MSB page will be described below with reference to FIG. 15. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharge potential may be less than an initial read voltage Vr5′ to be applied in this example.

During a period from T2 to T3, the voltage generator 122 may generate a fifth read voltage Vr5′ for a certain time, and the address decoder 121 may apply the fifth read voltage Vr5′, generated by the voltage generator 122, to the selected word line Selected WL. The fifth read voltage Vr5′ may be higher than the fifth read voltage Vr5 applied during the read operation S810. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a first read voltage Vr1′ having a level lower than that of the fifth read voltage Vr5′ by a fourth value ΔV4′, the voltage generator 122 may be underdriven to generate a voltage (e.g., voltage D′ in FIG. 15) lower than the first read voltage Vr1′ by a certain level. Here, the voltage generator 122 may be underdriven to a new underdrive level, in which an offset is applied to an initially set underdrive level (e.g., the underdrive level used in the read operation), under the control of the drive offset controller 132, and the new underdrive level in the read retry operation (e.g., voltage D′) may be different from the underdrive level (e.g., see voltage D in FIG. 11) in the read operation S810.

During a period from T3 to T4, the voltage generator 122 may generate the first read voltage Vr1′, and the address decoder 121 may apply the first read voltage Vr1′, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

As described above, the new underdrive level, in which the offset is applied to the underdrive level used in the read operation, may be used in the read retry operation, and thus operation speed may be further improved.

FIGS. 16, 17, and 18 are waveform diagrams for explaining an example of a read operation according to an embodiment of the present disclosure. In these examples, the read voltages are applied to be progressively higher over time and thus the voltage generator 122 may be overdriven at least once between application of adjacent read voltages.

An example of S810 of FIG. 8 will be described in detail below with reference to FIGS. 1, 2, 9, 10, and 11. When the memory cells are programmed according to the TLC scheme, the read operation may be sequentially performed in the order of a read operation on an LSB page, a read operation on a CSB page, and a read operation on an MSB page.

The read operation on the LSB page will be described below with reference to FIG. 16 where two read voltages are applied. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may be lower than the read voltages to be applied for the LSB page.

During a period from T2 to T3, the voltage generator 122 may generate the third read voltage Vr3 for a certain time, and the address decoder 121 may apply the third read voltage Vr3, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a seventh read voltage Vr7 having a level higher than that of the third read voltage Vr3 by a first value ΔV11, the voltage generator 122 may be overdriven to generate a voltage (e.g., voltage X in FIG. 16) higher than the seventh read voltage Vr7 by a certain level.

During a period from T3 to T4, the voltage generator 122 may generate the seventh read voltage Vr7, and the address decoder 121 may apply the seventh read voltage Vr7, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

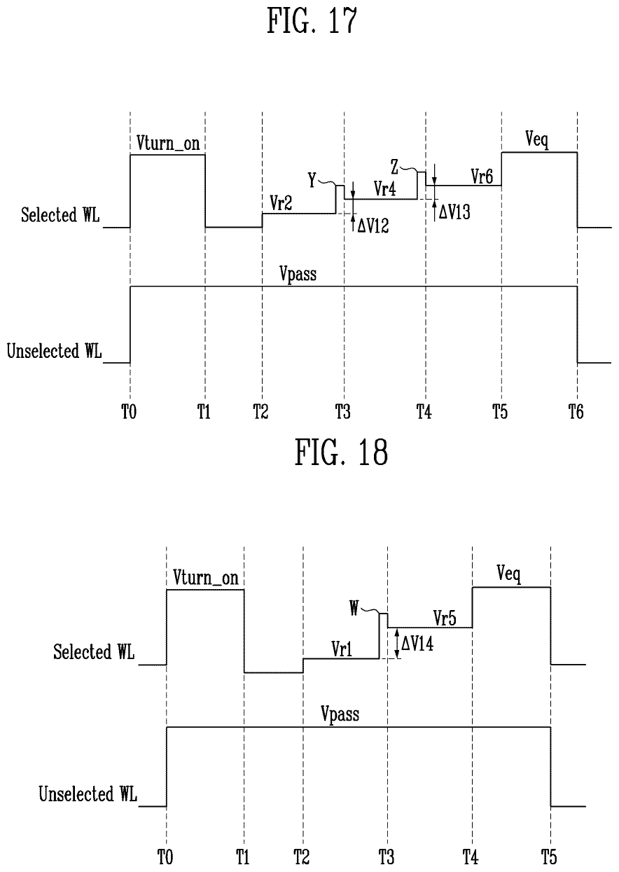

The read operation on the CSB page will be described below with reference to FIG. 17 where three read voltages are applied. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharge potential may be lower than all the read voltages to be applied for the CSB page.

During a period from T2 to T3, the voltage generator 122 may generate the second read voltage Vr2 for a certain time, and the address decoder 121 may apply the second read voltage Vr2, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a fourth read voltage Vr4 having a level higher than that of the second read voltage Vr2 by a second value ΔV12, the voltage generator 122 may be overdriven to generate a voltage (e.g., voltage Y in FIG. 17) higher than the fourth read voltage Vr4 by a certain level.

During a period from T3 to T4, the voltage generator 122 may generate the fourth read voltage Vr4 for a certain time, and the address decoder 121 may apply the fourth read voltage Vr4, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a sixth read voltage Vr6 having a level higher than that of the fourth read voltage Vr4 by a third value ΔV13, the voltage generator 122 may be overdriven to generate a voltage (e.g., voltage Z in FIG. 17) higher than the sixth read voltage Vr6 by a certain level.

During a period from T4 to T5, the voltage generator 122 may generate the sixth read voltage Vr6, and the address decoder 121 may apply the sixth read voltage Vr6, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T5 to T6, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

The read operation on the MSB page will be described below with reference to FIG. 18. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may be lower than all of the read voltages to be applied for the MSB page.

During a period from T2 to T3, the voltage generator 122 may generate a first read voltage Vr1 for a certain time, and the address decoder 121 may apply the first read voltage Vr1, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a fifth read voltage Vr5 having a level higher than that of the first read voltage Vr1 by a fourth value ΔV14, the voltage generator 122 may be overdriven to generate a voltage (e.g., voltage W in FIG. 18) higher than the fifth read voltage Vr5 by a certain level.

During a period from T3 to T4, the voltage generator 122 may generate the fifth read voltage Vr5, and the address decoder 121 may apply the fifth read voltage Vr5, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

As described above, the read voltages applied in the read operation on the LSB page, the read operation on the CSB page, and the read operation on the MSB page, respectively, may be sequentially applied to be progressively higher over the time periods provided for the LSB, CSB, and MSB page.

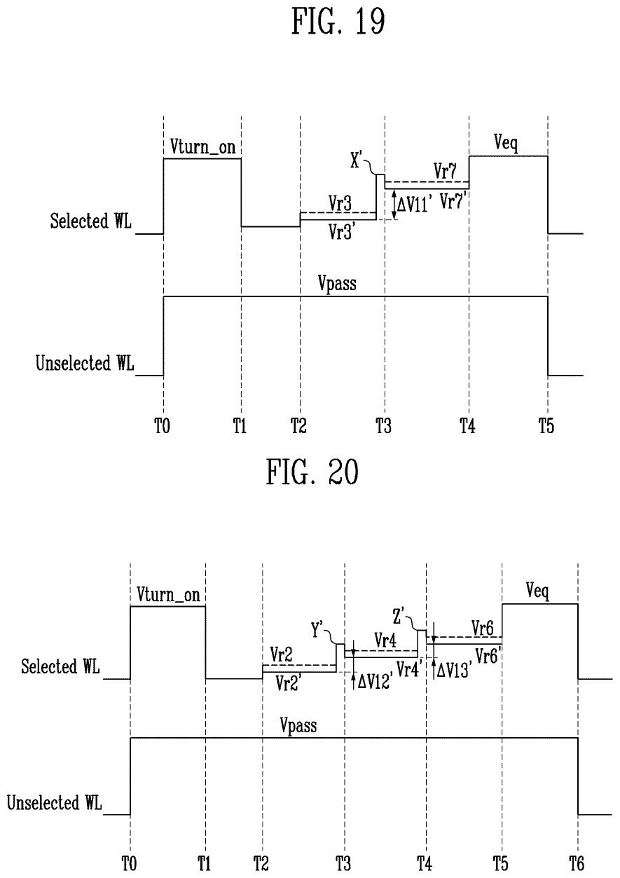

FIGS. 19, 20, and 21 are waveform diagrams for explaining an example of a read retry operation according to an embodiment of the present disclosure. The read retry operation may be performed after the memory controller 200 determines that the read operation performed in FIGS. 16, 17, and 18 has failed. The read retry operation according to an embodiment of the present disclosure will be described below with reference to FIGS. 2, 19, 20, and 21.

A read retry operation performed on an LSB page will be described below with reference to FIG. 19. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may be lower than all the read voltages applied for the LSB page during the read retry operation.

During a period from T2 to T3, the voltage generator 122 may generate a third read voltage Vr3′ for a certain time, and the address decoder 121 may apply the third read voltage Vr3′, generated by the voltage generator 122, to the selected word line Selected WL. The third read voltage Vr3′ may be lower than the third read voltage Vr3 applied for the LSB page in FIG. 16. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a seventh read voltage Vr7′ having a level higher than that of the third read voltage Vr3′ by a first value ΔV11′, the voltage generator 122 may be overdriven to generate a voltage (e.g., voltage X′ in FIG. 19) higher than the seventh read voltage Vr7′ by a certain level. Here, the voltage generator 122 may be overdriven to a new overdrive level, in which an offset is applied to an initially set overdrive level (e.g., the overdrive level used in the read operation), under the control of the drive offset controller 132. Thus, the new overdrive level in the read retry operation (e.g., voltage X′) may be different from the overdrive level (e.g., see voltage X in FIG. 16) in the read operation.

During a period from T3 to T4, the voltage generator 122 may generate the seventh read voltage Vr7′, and the address decoder 121 may apply the seventh read voltage Vr7′, generated by the voltage generator 122, to the selected word line Selected WL. The seventh read voltage Vr7′ may be lower than the seventh read voltage Vr7 applied for the LSB page during the read operation in FIG. 16. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

A read retry operation on a CSB page will be described below with reference to FIG. 20. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may be lower than all the read voltages applied for the CSB page during the read retry operation.

During a period from T2 to T3, the voltage generator 122 may generate a second read voltage Vr2′ for a certain time, and the address decoder 121 may apply the second read voltage Vr2′, generated by the voltage generator 122, to the selected word line Selected WL. The second read voltage Vr2′ may be lower than the read voltage Vr2 applied for the CSB page during the read operation in FIG. 17. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a fourth read voltage Vr4′ having a level higher than that of the second read voltage Vr2′ by a second value ΔV12′, the voltage generator 122 may be overdriven to generate a voltage (e.g., voltage Y′ in FIG. 20) higher than the fourth read voltage Vr4′ by a certain level. Here, the voltage generator 122 may be overdriven to a new overdrive level, in which an offset is applied to an initially set overdrive level (e.g., the overdrive level used in the read operation), under the control of the drive offset controller 132. Thus, the new overdrive level in the read retry operation (e.g., voltage Y′) may be different from the overdrive level (e.g., see voltage Y in FIG. 17) in the read operation.

During a period from T3 to T4, the voltage generator 122 may generate the fourth read voltage Vr4′ for a certain time, and the address decoder 121 may apply the fourth read voltage Vr4′, generated by the voltage generator 122, to the selected word line Selected WL. The fourth read voltage Vr4′ may be less than the fourth read voltage Vr4 applied during the read operation in FIG. 17. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a sixth read voltage Vr6′ having a level higher than that of the fourth read voltage Vr4′ by a third value ΔV13′, the voltage generator 122 may be overdriven to generate a voltage (e.g., voltage Z′ in FIG. 20) higher than the sixth read voltage Vr6′ by a certain level. Here, the voltage generator 122 may be overdriven to a new overdrive level, in which an offset is applied to an initially set overdrive level (e.g., the overdrive level used in the read operation), under the control of the drive offset controller 132. Thus, the new overdrive level in the read retry operation (e.g., voltage Z′) may be different from the overdrive level (e.g., see voltage Z in FIG. 17) in the read operation.

During a period from T4 to T5, the voltage generator 122 may generate the sixth read voltage Vr6′, and the address decoder 121 may apply the sixth read voltage Vr6′, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T5 to T6, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

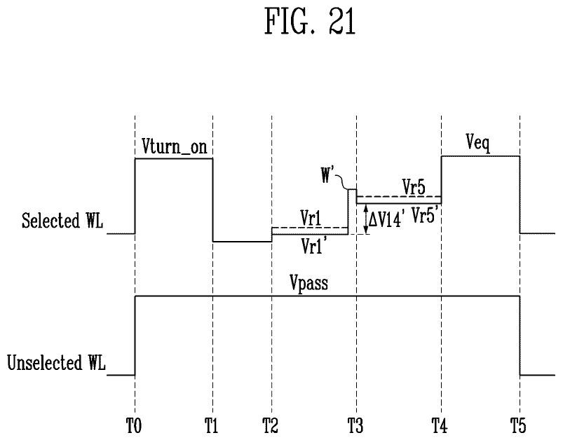

A read retry operation on an MSB page will be described below with reference to FIG. 21. During a period from T0 to T1, the voltage generator 122 may generate a turn-on voltage Vturn_on to be applied to a selected word line Selected WL, and a pass voltage Vpass to be applied to unselected word lines Unselected WL. The address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation. The discharged potential may be lower than all the read voltages applied to the MSB page.

During a period from T2 to T3, the voltage generator 122 may generate a first read voltage Vr1′ for a certain time, and the address decoder 121 may apply the first read voltage Vr1′, generated by the voltage generator 122, to the selected word line Selected WL. The first read voltage VR1′ may be lower than the first read voltage Vr1 applied to the MSB page during the read operation in FIG. 18. The page buffer group 123 may read data DATA from the memory cells connected to the selected word line Selected WL through the bit lines BL1 to BLm, and may store the read data DATA in the first to m-th page buffers PB1 to PBm.

Thereafter, in order to quickly generate a fifth read voltage Vr5′ having a level higher than that of the first read voltage Vr1′ by a fourth value ΔV14′, the voltage generator 122 may be overdriven to generate a voltage (e.g., voltage W′ in FIG. 21) higher than the fifth read voltage Vr5′ by a certain level. Here, the voltage generator 122 may be overdriven to a new overdrive level, in which an offset is applied to an initially set overdrive level (e.g., the overdrive level used in the read operation), under the control of the drive offset controller 132. For example, the new overdrive level in the read retry operation (e.g., voltage W′) may be different from the overdrive level (e.g., see voltage W in FIG. 18) in the read operation.

During a period from T3 to T4, the voltage generator 122 may generate the fifth read voltage Vr5′, and the address decoder 121 may apply the fifth read voltage Vr5′, generated by the voltage generator 122, to the selected word line Selected WL. The fifth read voltage Vr5′ may be lower than the fifth read voltage Vr5 applied to the MSB page during the read operation. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

As described above, during the read operation and the read retry operation, when a relatively low read voltage is first applied to a selected word line and a relatively high read voltage is then applied to the selected word line, operation speed may be further improved by using a new overdrive level, in which an offset is applied to an overdrive level used in the read operation, in the read retry operation.

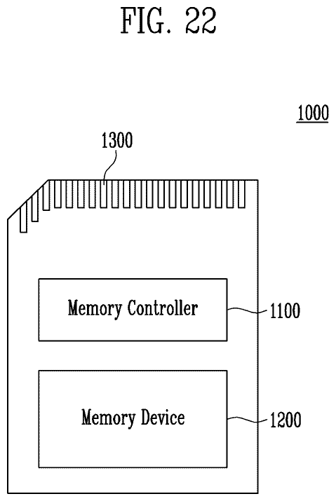

FIG. 22 is a block diagram illustrating a memory card system 1000 to which the memory system 50 according to an embodiment of the present disclosure is applied.

Referring to FIG. 22, the memory card system 1000 includes a memory controller 1100, a memory device 1200, and a connector 1300.

The memory controller 1100 is connected to the memory device 1200. The memory controller 1100 may access the memory device 1200. For example, the memory controller 1100 may control read, write, erase, and background operations of the memory device 1200. The memory controller 1100 may provide an interface between the memory device 1200 and a host. The memory controller 1100 may run firmware for controlling the memory device 1200. The memory controller 1100 may be implemented in the same manner as the memory controller 200, described above with reference to FIG. 1. The memory device 1200 may be implemented in the same manner as the memory device 100, described above with reference to FIG. 1.

In an embodiment, the memory controller 1100 may include components, such as a random access memory (RAM), a processor, a host interface, a memory interface, and an error correction circuit.

The memory controller 1100 may communicate with an external device through the connector 1300. The memory controller 1100 may communicate with an external device (e.g., a host) based on a specific communication standard. In an embodiment, the memory controller 1100 may communicate with the external device through at least one of various communication protocols such as universal serial bus (USB), multimedia card (MMC), embedded MMC (eMMC), peripheral component interconnection (PCI), PCI-express (PCI-e or PCIe), an advanced technology attachment (ATA) protocol, a serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 1300 may be defined by at least one of the above-described various communication standards.

In an embodiment, the memory device 1200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin transfer torque magnetic RAM (STT-MRAM).

The memory controller 1100 and the memory device 1200 may be integrated into a single semiconductor device to form a memory card. For example, the memory controller 1100 and the memory device 1200 may be integrated into a single semiconductor device to form a memory card such as a personal computer memory card international association (PCMCIA), a compact flash card (CF), a smart media card (SM or SMC), a memory stick, a multimedia card (MMC, RS-MMC, MMCmicro or eMMC), a secure digital (SD) card (SD, miniSD, microSD, or SDHC), or a universal flash storage (UFS).

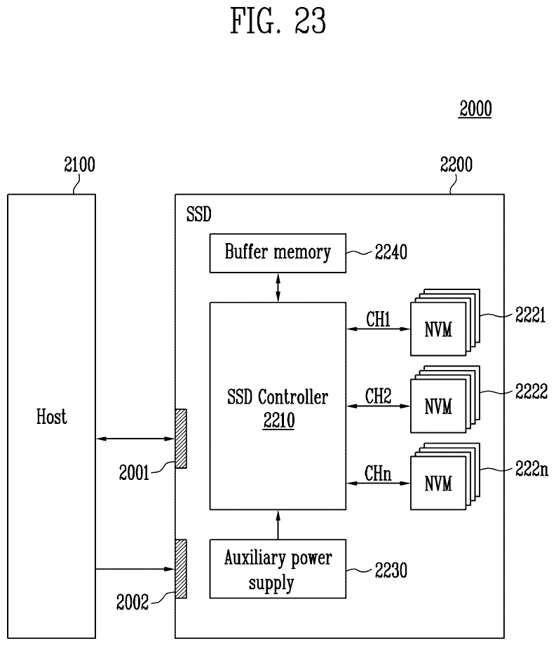

FIG. 23 is a block diagram illustrating a solid state drive (SSD) system 2000 to which the memory system 50 according to an embodiment of the present disclosure is applied.

Referring to FIG. 23, the SSD system 2000 may include a host 2100 and an SSD 2200. The SSD 2200 may exchange signals with the host 2100 through a signal connector 2001, and may receive power through a power connector 2002. The SSD 2200 may include an SSD controller 2210, a plurality of flash memories 2221 to 222n, an auxiliary power supply 2230, and a buffer memory 2240.

In accordance with an embodiment of the present disclosure, the SSD controller 2210 may perform the function of the memory controller 200, described above with reference to FIG. 1.

The SSD controller 2210 may control the plurality of flash memories 2221 to 222n in response to the signals received from the host 2100. In an embodiment, the signals may be signals based on the interfaces of the host 2100 and the SSD 2200. For example, the signals may be signals defined by at least one of interfaces such as universal serial bus (USB), multimedia card (MMC), embedded MMC (eMMC), peripheral component interconnection (PCI), PCI-express (PCI-e or PCIe), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The auxiliary power supply 2230 may be connected to the host 2100 through the power connector 2002. The auxiliary power supply 2230 may be supplied with power from the host 2100, and may be charged. The auxiliary power supply 2230 may supply the power of the SSD 2200 when the supply of power from the host 2100 is not smoothly performed. In an embodiment, the auxiliary power supply 2230 may be located inside the SSD 2200 or located outside the SSD 2200. For example, the auxiliary power supply 2230 may be located on a main board, and may provide auxiliary power to the SSD 2200.

The buffer memory 2240 functions as a buffer memory of the SSD 2200. For example, the buffer memory 2240 may temporarily store data received from the host 2100 or data received from the plurality of flash memories 2221 to 222n or may temporarily store metadata (e.g., mapping tables) of the flash memories 2221 to 222n. The buffer memory 2240 may include volatile memories, such as DRAM, SDRAM, DDR SDRAM, LPDDR SDRAM, and GRAM, or nonvolatile memories, such as FRAM, ReRAM, STT-MRAM, and PRAM.

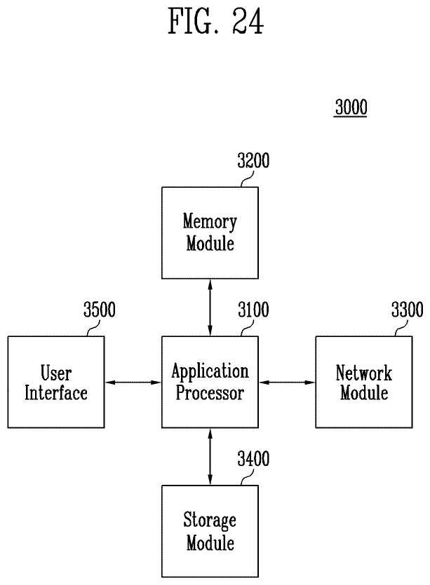

FIG. 24 is a block diagram illustrating a user system 3000 to which the memory system 50 according to an embodiment of the present disclosure is applied.

Referring to FIG. 24, the user system 3000 may include an application processor 3100, a memory module 3200, a network module 3300, a storage module 3400, and a user interface 3500.

The application processor 3100 may run components included in the user system 3000, an operating system (OS) or a user program. In an embodiment, the application processor 3100 may include controllers, interfaces, graphic engines, etc. for controlling the components included in the user system 3000. The application processor 3100 may be provided as a system-on-chip (SoC).

The memory module 3200 may function as a main memory, a working memory, a buffer memory or a cache memory of the user system 3000. The memory module 3200 may include volatile RAMs such as DRAM, SDRAM, DDR SDRAM, DDR2 SDRAM, DDR3 SDRAM, LPDDR SDRAM, LPDDR2 SDRAM, and LPDDR3 SDRAM, or nonvolatile RAMs such as PRAM, ReRAM, MRAM, and FRAM. In an embodiment, the application processor 3100 and the memory module 3200 may be packaged based on a package-on-package (POP), and may then be provided as a single semiconductor package.

The network module 3300 may communicate with external devices. In an embodiment, the network module 3300 may support wireless communication, such as code division multiple access (CDMA), a global system for mobile communication (GSM), wideband CDMA (WCDMA), CDMA-2000, time division multiple access (TDMA), long term evolution (LTE), WiMAX, WLAN, UWB, Bluetooth, or Wi-Fi. In an embodiment, the network module 3300 may be included in the application processor 3100.

The storage module 3400 may store data. For example, the storage module 3400 may store data received from the application processor 3100. Alternatively, the storage module 3400 may transmit the data stored in the storage module 3400 to the application processor 3100. In an embodiment, the storage module 3400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 3400 may be provided as a removable storage medium (removable drive), such as a memory card or an external drive of the user system 3000.

In an embodiment, the storage module 3400 may include a plurality of nonvolatile memory devices, each of which may be operated in the same manner as the memory device 100, described above with reference to FIG. 1. The storage module 3400 may be operated in the same manner as the memory system 50, described above with reference to FIG. 1.

The user interface 3500 may include interfaces which input data or instructions to the application processor 3100 or output data to external devices. In an embodiment, the user interface 3500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 3500 may include user output interfaces such as an a liquid crystal display (LCD), an organic light emitting diode (OLED) display device, an active matrix OLED (AMOLED) display device, an LED, a speaker, and a monitor.

According to the present disclosure, the potential level of a word line can be quickly charged or discharged to a set level during a read operation, thus improving operation speed.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A memory device, comprising:
a memory block connected to a plurality of word lines;
a voltage generator configured to generate a plurality of read voltages during a read operation and a plurality of read voltages during a read retry operation, the plurality of read voltages generated during the read operation and the plurality of read voltages generated during the read retry operation to be applied to a selected word line among the plurality of word lines ; and
a control logic configured to control the voltage generator to perform the read operation and the read retry operation on the memory block, wherein the voltage generator is underdriven or overdriven to generate each of the plurality of read voltages based on an underdrive level or and an overdrive level used respectively corresponding to the plurality of read voltages, and
wherein the control logic is configured to control the voltage generator to perform the read retry operation by applying an offset to the underdrive level or the overdrive level based on a variation between the plurality of read voltages generated in the read operation and the plurality of read voltages generated in the read retry operation, levels of the plurality of read voltages generated in the read retry operation being newly set in the read retry operation.

2. The memory device according to claim 1, wherein the control logic is configured to set an underdrive offset value or an overdrive offset value of each of the plurality of read voltages to be used in the read retry operation, based on respective difference values between the plurality of read voltages used in the read operation and the plurality of read voltages to be used in the read retry operation and proportional constant values respectively corresponding to the plurality of read voltages.

3. The memory device according to claim 2, wherein the control logic is configured to:
set a new underdrive level for the read retry operation by applying the underdrive offset value to the underdrive level used for the read operation, or
set a new overdrive level for the read retry operation by applying the overdrive offset value to the overdrive level used for the read operation.

4. The memory device according to claim 3, wherein the control logic comprises:
a read voltage level controller configured to set levels of the plurality of read voltages during the read operation and the read retry operation; and
a drive offset controller configured to control the voltage generator by setting the overdrive level or the underdrive level during the read operation.

5. The memory device according to claim 4, wherein the drive offset controller is configured to set the underdrive offset value or the overdrive offset value of each of the plurality of read voltages to be used in the read retry operation, based on the respective difference values between the plurality of read voltages used in the read operation and the plurality of read voltages to be used in the read retry operation and the proportional constant values respectively corresponding to the plurality of read voltages.

6. The memory device according to claim 4, wherein the drive offset controller is configured to control the voltage generator to generate a voltage having the new underdrive level or the new overdrive level in such a way as to:
set the new underdrive level for the read retry operation by applying the underdrive offset value to the underdrive level, or
set the new overdrive level for the read retry operation by applying the overdrive offset value to the overdrive level.

7. The memory device according to claim 1, wherein the voltage generator is configured to first apply a read voltage having a relatively high level to the selected word line during the read operation or the read retry operation and thereafter apply a read voltage having a relatively low level to the selected word line.

8. The memory device according to claim 7, wherein the control logic is configured to control the voltage generator to allow the read voltage having the relatively high level to be underdriven to a level less than that of the read voltage having the relatively low level before the read voltage having the relatively low level is applied to the selected word line.

9. The memory device according to claim 1, wherein the voltage generator is configured to first apply a read voltage having a relatively low level to the selected word line and thereafter apply a read voltage having a relatively high level to the selected word line, during the read operation or the read retry operation.

10. The memory device according to claim 9, wherein the control logic is configured to control the voltage generator to allow the read voltage having the relatively low level to be overdriven to a level greater than that of the read voltage having the relatively high level before the read voltage having the relatively high level is applied to the selected word line.

11. A memory system, comprising:
a memory device configured to store data, and read and output data during a read operation; and
a memory controller configured to receive the data from the memory device and control the memory device to perform a read retry operation based on a number of error bits contained in the received data,
wherein the memory device is configured to set an underdrive level or an overdrive level during the read retry operation based on a level variation between read voltages used during the read operation and read voltages to be used during the read retry operation and to generate the read voltages at the underdrive level or the overdrive level during the read retry operation.

12. The memory system according to claim 11, wherein the memory device comprises:
a memory block connected to a plurality of word lines;
a voltage generator configured to generate the read voltages during the read operation and the read voltages during the read retry operation to be applied to a selected word line among the plurality of word lines; and
a control logic configured to control the voltage generator to perform the read operation and the read retry operation on the memory block, wherein the voltage generator is configured to generate each of the read voltages during the read retry operation at the underdrive level or the overdrive level, and
wherein the control logic is configured to control the voltage generator to perform the read retry operation by applying an offset to the underdrive level or the overdrive level based on a variation between the read voltages used in the read operation and the read voltages used during the read retry operation, levels of the read voltages used in the read retry operation being newly set in the read retry operation.

13. The memory system according to claim 12, wherein the control logic is configured to set an underdrive offset value or an overdrive offset value of each of the read voltages to be used in the read retry operation, based on respective difference values between the read voltages used in the read operation and the read voltages to be used in the read retry operation and proportional constant values respectively corresponding to the read voltages.

14. The memory system according to claim 13, wherein the control logic is configured to:
set a new underdrive level for the read retry operation by applying the underdrive offset value to the underdrive level, or
set a new overdrive level for the read retry operation by applying the overdrive offset value to the overdrive level.

15. The memory system according to claim 14, wherein the control logic comprises:
a read voltage level controller configured to set levels of the plurality of read voltages during the read operation and the read retry operation; and
a drive offset controller configured to control the voltage generator by setting the overdrive level or the underdrive level during the read operation.

16. The memory system according to claim 15, wherein the drive offset controller is configured to set the underdrive offset value or the overdrive offset value of each of the read voltages to be used in the read retry operation, based on the respective difference values between the read voltages used in the read operation and the read voltages to be used in the read retry operation and the proportional constant values respectively corresponding to the read voltages.

17. The memory system according to claim 12, wherein the voltage generator is configured to first apply a read voltage having a relatively high level to the selected word line during the read operation or the read retry operation and thereafter apply a read voltage having a relatively low level to the selected word line.

18. The memory system according to claim 17, wherein the control logic is configured to control the voltage generator to allow the read voltage having the relatively high level to be underdriven to a level less than that of the read voltage having the relatively low level before the read voltage having the relatively low level is applied to the selected word line.

19. The memory system according to claim 12, wherein the voltage generator is configured to first apply a read voltage having a relatively low level to the selected word line and thereafter apply a read voltage having a relatively high level to the selected word line, during the read operation or the read retry operation.

20. The memory system according to claim 19, wherein the control logic is configured to control the voltage generator to allow the read voltage having the relatively low level to be overdriven to a level greater than that of the read voltage having the relatively high level before the read voltage having the relatively high level is applied to the selected word line.

21. A method of operating a memory device, comprising:
performing a read operation on memory cells connected to a selected word line using a plurality of read voltages; and
when the read operation is determined to have failed, performing a read retry operation on the memory cells using a plurality of new read voltages obtained by changing levels of the plurality of read voltages used in the read operation, wherein the performing of the read retry operation includes adjusting an underdrive level or an overdrive level of each of the plurality of new read voltages based on a variation between each of the plurality of read voltages used in the read operation and each of the plurality of new read voltages used in the read retry operation.

22. The method according to claim 21, wherein the performing of the read retry operation comprises:
setting an underdrive offset value or an overdrive offset value of each of the plurality of new read voltages to be used in the read retry operation, based on respective difference values between the plurality of read voltages used in the read operation and the plurality of new read voltages to be used in the read retry operation and proportional constant values respectively corresponding to the plurality of read voltages;
setting a new underdrive level or a new overdrive level of each of the plurality of new read voltages by applying the underdrive offset value or the overdrive offset value to an underdrive level or an overdrive level of each of the plurality of read voltages; and
applying the plurality of new read voltages to the selected word line.

23. The method according to claim 22, wherein, during the read retry operation, the plurality of new read voltages are applied such that a read voltage having a relatively high level is first applied to the selected word line and thereafter a read voltage having a relatively low level is applied to the selected word line.

24. The method according to claim 23, wherein, during the read retry operation, the read voltage having the relatively high level is underdriven to a level less than that of the read voltage having the relatively low level before the read voltage having the relatively low level is applied to the selected word line.

25. The method according to claim 22, wherein, during the read retry operation, a read voltage having a relatively low level is first applied to the selected word line, and thereafter a read voltage having a relatively high level is applied to the selected word line.

26. The method according to claim 25, wherein, during the read retry operation, the read voltage having the relatively low level is overdriven to a level greater than that of the read voltage having the relatively high level before the read voltage having the relatively high level is applied to the selected word line.
